(19) United States
(12) Patent Application Publication
(10) Pub. No.: US 2026/0195874 A1
(43) Pub. Date: Jul. 9, 2026

(54) METHOD FOR MEASURING MELT GAP

(71) Applicant: SK SILTRON CO., LTD., Gumi-si (KR)

(72) Inventors: Je Gyu OH, Gumi-si (KR); Do Hyun PARK, Gumi-si (KR); Han Sol JUNG, Gumi-si (KR); Jong Min KANG, Gumi-si (KR)

(21) Appl. No.: 19/426,635

(22) Filed: Dec. 19, 2025

(30) Foreign Application Priority Data
Jan. 8, 2025 (KR) 10-2025-0002968

(51) Int. Cl. G06T 5/80; C30B 15/14; C30B 15/26; C30B 29/06; G06T 7/00; G06T 7/13; G06T 7/564; G06T 7/60

(52) U.S. Cl. CPC G06T 5/80; C30B 15/14; C30B 15/26; C30B 29/06; G06T 7/0002; G06T 7/13; G06T 7/564; G06T 7/60

(57) ABSTRACT

The embodiment relates to a method for measuring a melt gap capable of improving the measurement accuracy of the melt gap using a reflection image of a scale load.

According to an aspect of the embodiment, a method for measuring a melt gap for single crystal growth is provided, and the method includes a first step of acquiring an image including a scale rod and reflection image thereof in a silicon melt during single crystal ingot growth; a second step of correcting the shape of the reflection image acquired in the first step to a regular ellipse if the shape of the reflection image is an irregular ellipse; and a third step of calculating the distance between the corrected reflection image in the second step and the scale rod as the melt gap.

### CROSS-REFERENCE TO RELATED APPLICATION

The subject application claims priority to Korean Patent Application Number 10-2025-0002968, filed on Jan. 8, 2025, the entire content of which is incorporated herein by reference.

### BACKGROUND

The embodiment relates to a method for measuring a melt gap capable of improving the measurement accuracy of the melt gap using a reflection image of a scale load.

Typically, to manufacture silicon wafers, single-crystal silicon must first be grown into an ingot, and, with respect to this, the Czochralski (CZ) method can be applied. Such silicon single-crystal growth apparatus includes a thermal shielding member to prevent heat radiating from the surface of the silicon melt and the heater from being transferred to the silicon single-crystal ingot.

However, when installing the thermal shielding member, a certain distance must be maintained between the lower portion of the thermal shielding member and the surface of the silicon melt, and this distance is referred to as a melt gap, and maintaining a consistent melt gap is crucial for improving the quality and productivity of silicon single-crystal ingots.

Therefore, once the melting process for the silicon melt is complete, the melt gap can be measured by bringing the lower end of the thermal shielding member (for example, a scale rod) into contact with the surface of the silicon melt to set or measure the melt gap.

A single crystal ingot growth apparatus disclosed in Korean Patent Publication No. 2014-0097834 includes a chamber having a view port, a crucible containing a silicon melt as a single crystal growth raw material inside the chamber, a heat shielding part disposed above the crucible, a scale rod for measuring a melt gap, which is a distance between the heat shielding part and the silicon melt, and a camera for capturing an image of the scale rod and a reflection image thereof generated on the surface of the silicon melt.

As a single crystal ingot is lifted from a silicon melt, the silicon melt surrounding the single crystal forms a steeper curved surface due to surface tension as the radial distance from the single crystal decreases.

However, as the diameter of the single crystal ingot increases, the reflection image of the scale rod input to the camera becomes closer to the single crystal ingot, and consequently, the reflection image of the scale rod reflected in the silicon melt, which forms the steep curved surface, becomes deformed into an irregular ellipse. Furthermore, according to the positions and angles of the scale rod, the single crystal, and the camera, the reflection image of the scale rod also becomes deformed into an irregular ellipse when the reflection image thereof is disposed close to the single crystal ingot.

According to the prior art, the melt gap is measured using pattern recognition when the reflection image of the scale rod becomes deformed into an irregular ellipse, and thus this causes measurement errors of the melt gap, hindering accurate melt gap control, and increases the rate of crystal quality defects, such as crystal defects and oxygen concentration.

### SUMMARY

An object of the present embodiment is to solve the aforementioned problems and other problems.

Another object of the present embodiment is to provide a method for measuring a melt gap that can improve the measurement accuracy of the melt gap using the reflection image of a scale load.

According to one aspect of the embodiment, a method for measuring a melt gap for single crystal growth is provided, and the method includes a first step of acquiring an image including a scale rod and reflection image thereof in a silicon melt during single crystal ingot growth; a second step of correcting the shape of the reflection image acquired in the first step to a regular ellipse if the shape of the reflection image is an irregular ellipse; and a third step of calculating the distance between the corrected reflection image in the second step and the scale rod as the melt gap.

According to one aspect of the embodiment, the second step may include a first process of selecting an undeformed curve among the irregular ellipses; and a second process of calculating center coordinates of a virtual ellipse established based on the undeformed curve selected in the first process.

According to one aspect of the embodiment, in the first process, a rectangle inscribed by the irregular ellipse may be formed, and a curve between two contact points inscribed by the irregular ellipse in the area of the rectangle farthest from the single crystal ingot may be selected as the undeformed curve.

According to one aspect of the embodiment, in the second process, the coordinates of the intersection of the two contact points and the perpendicular line may be calculated as the center coordinates of the virtual ellipse.

According to one aspect of the embodiment, in the third step, the distance between the reflection image corrected in the second step and the image of the scale load may be calculated in pixel unit, and the pixel unit may be automatically corrected to a melt gap in length unit.

According to one aspect of the embodiment, in the first step, the image may be captured by a camera installed on the view port side, and the camera may be moved in three-axis direction by a moving part according to the position of the scale rod.

According to one aspect of the embodiment, the method for measuring a melt gap may further include a fourth step of precisely controlling the height of the crucible so that the melt gap calculated in the third step reaches a target melt gap.

According to one aspect of the embodiment, the scale load may be made of quartz material so as to be close to the silicon melt and not affect the yield.

According to one aspect of the embodiment, the second step may include a process of not performing separate correction if the reflection image shape in the acquired image is a regular ellipse.

According to one aspect of the embodiment, a heat shielding part disposed between the scale rod and the silicon melt and coupled to the lower end of the scale rod may block heat from escaping upward from the silicon melt and cool the single crystal ingot.

According to the embodiment, even if the reflection image of the scale load is deformed into an irregular ellipse, the melt gap can be accurately calculated by correcting the irregular ellipse into a regular ellipse, so there is an advantage in that the melt gap can be accurately controlled to improve the crystal quality such as crystal defects and oxygen concentration.

### BRIEF DESCRIPTION OF THE DRAWINGS

FIG. 1 is a cross-sectional side view illustrating a single crystal ingot growth apparatus according to an embodiment.

FIG. 2 is a flowchart illustrating a method for measuring a melt gap according to an embodiment.

FIG. 3 is a diagram illustrating the reflection image shape of a scale rod before and after correction according to an embodiment.

### DETAILED DESCRIPTION OF THE EMBODIMENTS

Hereinafter, the present embodiment will be described in detail with reference to the attached drawings.

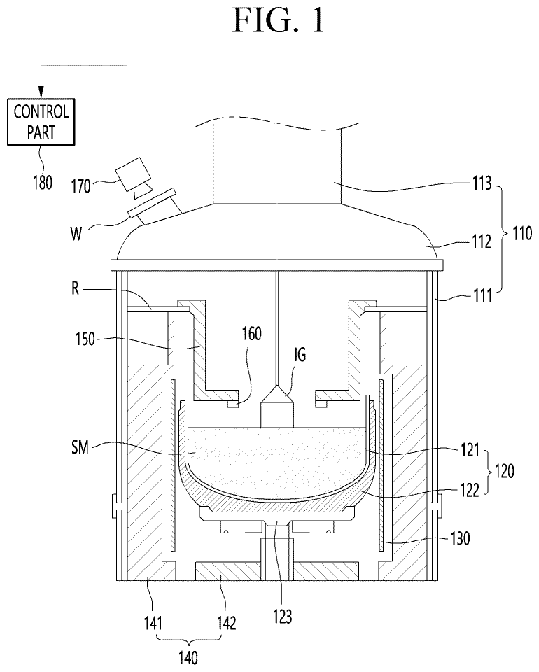

FIG. 1 is a cross-sectional side view illustrating a single crystal ingot growth apparatus according to an embodiment.

As illustrated in FIG. 1, the single crystal ingot growth apparatus of the embodiment may include a chamber 110, a crucible 120, a heater 130, an insulating member 140, a heat shielding part 150, a scale rod 160, a camera 170, and a control part 180.

The chamber 110 is a sealed space that provides a growth environment for growing a single crystal ingot I and may be equipped with a view port W for observing the interior thereof.

The chamber 110 may be divided into a body chamber 111, a dome chamber 112, and a pull chamber 113 according to the attachment location.

The view port W may be installed in one area of the dome chamber 112, but is not limited thereto. In addition, a plurality of view ports W may be provided to correspond to the number of cameras 170.

The body chamber 111 may be disposed at the lower portion, and the dome chamber 112 may be disposed at the upper end of the body chamber 111 to function as a cover. The body chamber 111 and the dome chamber 112 provide an environment for growing polycrystalline silicon into a single crystal ingot I and may be cylindrical with an internal accommodation space.

The pull chamber 113 may be disposed at the upper end of the dome chamber 112 and may be a space for lifting the grown single crystal ingot I. Therefore, the single crystal ingot I grown in the space formed by the body chamber 111 and the dome chamber 112 may be lifted upward by the pull chamber 113.

The crucible 120 can be provided within a chamber 110, for example, a body chamber 111, and can accommodate a raw silicon melt SM for growing a single crystal ingot I. The crucible 120 may be composed of an inner peripheral part 121 made of quartz and an outer peripheral part 122 made of graphite, but is not limited thereto.

A crucible support 123 is provided at the lower portion of the crucible 120, and the crucible support 123 can support the crucible 120, rotate the crucible 120, or raise or lower the crucible 120.

The heater 130 may be disposed within the chamber 110, for example, the body chamber 111, to be spaced apart from the outer peripheral surface of the crucible 120, and may be a resistance heater or an induction heater, but is not limited thereto.

When the heater 130 heats the crucible 120, the high-purity polycrystalline mass loaded within the heated crucible 120 may melt to form a silicon melt SM.

The insulating member 140 may be provided to prevent heat from escaping from the chamber 110 to the outside. The insulating member may include a side insulating member 141 disposed between the heater 130 and the side wall of the body chamber 111, and a lower insulating member 142 disposed between the heater 130 and the bottom of the body chamber 111.

The heat shielding part 150 is installed to hang from the upper portion of the crucible 120 and blocks heat from escaping upward from the silicon melt SM contained within the crucible 120 while simultaneously cooling a single crystal ingot IG lifted from the silicon melt SM.

The scale rod 160 is attached to the lower end of the heat shielding part 150 and can be disposed on the silicon melt SM contained within the crucible 120. The scale rod 160 is made of quartz so as not to affect the yield due to the proximity thereof to the high-temperature silicon melt SM.

The distance between the scale rod 160 and the silicon melt SM is defined as the melt gap M/G. This melt gap M/G determines the temperature environment of the single crystal ingot IG and affects the quality of the single crystal ingot, such as crystal defects and oxygen concentration, which are affected by changes in thermal history.

The camera 170 can be installed on the view port W side and can capture an image of a specific area including the lower portion of the scale rod 160 and the reflection image thereof on the silicon melt SM.

A moving part (not illustrated) capable of moving the camera 170 in three-axis direction may be additionally provided and according to the position of the scale rod 160, the camera 170 can be fixed on the view port W or moved by the moving part (not illustrated).

The control part 180 can correct the images captured by the camera 170 to extract an accurate melt gap M/G.

The control part 180 may include an input part that receives a reflection image of the scale rod 160 reflected in the silicon melt and an image including the scale rod 160, a correction part that corrects the shape of the reflection image input to the input part to a regular ellipse if the shape of the reflection image is an irregular ellipse, and a calculation part that calculates the distance between the reflection image and the scale rod 160 from the corrected image by the correction part as a melt gap. An embodiment in which the control part 180 corrects the irregular ellipse reflection image to a regular ellipse reflection image will be described in detail below.

The control part 180 extracts an accurate melt gap M/G as described above, and then precisely controls the height of the crucible 120 so that the melt gap M/G reaches a target melt gap, thereby improving the quality of the single crystal ingot IG, such as crystal defects and oxygen concentration.

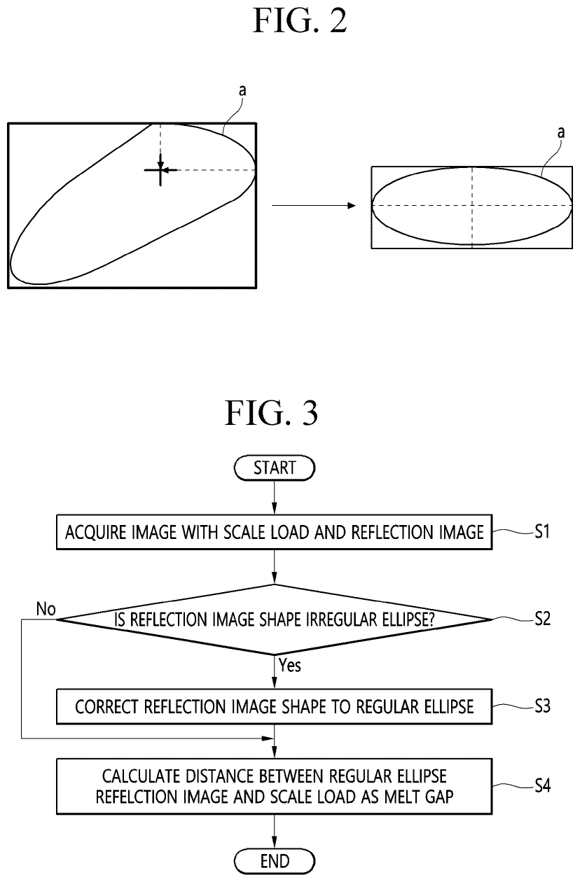

FIG. 2 is a flowchart illustrating a method for measuring a melt gap according to an embodiment, and FIG. 3 is a diagram illustrating the reflection image shape of a scale rod before and after correction according to an embodiment.

During single crystal ingot growth, an image including the scale rod and the reflection image thereof in the silicon melt are acquired (See S1).

A camera captures an image of the corresponding area, and a control part receives the image from the camera.

If the reflection image shape in the acquired image is an irregular ellipse, the irregular ellipse is corrected to a regular ellipse (See S2 and S3).

If the reflection image shape is an irregular ellipse, an undeformed curve a is selected among the irregular ellipses. For example, a rectangle inscribed by the irregular ellipse can be formed, and the curve between the two contact points inscribed by the irregular ellipse in the area farthest from the single crystal ingot among the rectangle can be selected as the undeformed curve a.

Once the undeformed curve a is selected, the center coordinates of the virtual ellipse can be calculated based on the undeformed curve a and the irregular ellipse can be corrected to a virtual regular ellipse.

Of course, if the reflection image shape in the acquired image is a regular ellipse, no separate correction is required.

The distance between the regular ellipse reflection image and the scale rod in the acquired or corrected image is calculated as the melt gap (See S4).

The distance between the reflection image and the scale rod in the image can be calculated in pixel units, and the pixel units can be automatically corrected to a melt gap in length units.

In this way, even if the reflection image of the scale rod is deformed into an irregular ellipse, the melt gap can be accurately calculated by correcting the irregular ellipse to a regular ellipse, and furthermore, the process can be precisely controlled based on the accurate melt gap, allowing for precise management of thermal history during the ingot growth process, thereby improving crystal quality, such as crystal defects and oxygen concentration.

The above description merely exemplifies the technical idea of the present invention and those skilled in the art will appreciate that various modifications and variations can be made without departing from the essential characteristics of the present invention.

Therefore, the embodiments disclosed in the present invention are intended to illustrate, rather than limit, the technical idea of the present invention, and the scope of the technical idea of the present invention is not limited by these embodiments.

The scope of protection of the present invention should be construed in accordance with the following claims, and all technical ideas within the scope equivalent thereto should be construed as being included within the scope of the present invention.

Explanation of symbols

| | |
|---|---|
| 110: chamber | 120: crucible |
| 130: heater | 140: insulating member |
| 150: heat shielding member | 160: scale rod |
| 170: camera | 180: control part |

What is claimed is:

1. A method for measuring a melt gap for single crystal growth, comprising:
a first step of acquiring an image including a scale rod and reflection image thereof in a silicon melt during single crystal ingot growth;
a second step of correcting the shape of the reflection image acquired in the first step to a regular ellipse if the shape of the reflection image is an irregular ellipse; and
a third step of calculating the distance between the corrected reflection image in the second step and the scale rod as the melt gap.

2. The method for measuring a melt gap of claim 1,
wherein the second step includes:
a first process of selecting an undeformed curve among the irregular ellipses; and
a second process of calculating center coordinates of a virtual ellipse established based on the undeformed curve selected in the first process.

3. The method for measuring a melt gap of claim 2,
wherein, in the first process, a rectangle inscribed by the irregular ellipse is formed, and a curve between two contact points inscribed by the irregular ellipse in the area of the rectangle farthest from the single crystal ingot is selected as the undeformed curve.

4. The method for measuring a melt gap of claim 3,
wherein, in the second process, the coordinates of the intersection of the two contact points and the perpendicular line are calculated as the center coordinates of the virtual ellipse.

5. The method for measuring a melt gap of claim 4,
wherein, in the third step, the distance between the reflection image corrected in the second step and the image of the scale load is calculated in pixel unit, and the pixel unit is automatically corrected to a melt gap in length unit.

6. The method for measuring a melt gap of claim 1,
wherein, in the first step, the image is captured by a camera (170) installed on the view port (W) side, and the camera (170) can be moved in three-axis direction by a moving part according to the position of the scale rod (160).

7. The method for measuring a melt gap of claim 1, further comprising:
a fourth step of precisely controlling the height of the crucible (120) so that the melt gap (M/G) calculated in the third step reaches a target melt gap.

8. The method for measuring a melt gap of claim 1,
wherein the scale load (160) is made of quartz material so as to be close to the silicon melt (SM) and not affect the yield.

9. The method for measuring a melt gap of claim 1,
wherein the second step includes a process of not performing separate correction if the reflection image shape in the acquired image is a regular ellipse.

10. The method for measuring a melt gap of claim 1,
wherein a heat shielding part (150) disposed between the scale rod (160) and the silicon melt (SM) and coupled to the lower end of the scale rod (160) blocks heat from escaping upward from the silicon melt (SM) and cools the single crystal ingot (IG).
